(19) United States
(12) Patent Application Publication
(10) Pub. No.: US 2025/0359285 A1
(43) Pub. Date: Nov. 20, 2025

(54) Backside Via and Dual Side Power Rail For Epitaxial Source/Drain Structure

(71) Applicant: Taiwan Semiconductor Manufacturing Company, Ltd., Hsin-Chu (TW)

(72) Inventors: Po-Yu Huang, Hsinchu (TW); Shih-Chieh Wu, Hsinchu (TW); I-Wen Wu, Hsinchu City (TW); Chen-Ming Lee, Yangmei City (TW); Mei-Yun Wang, Hsinchu (TW)

(21) Appl. No.: 19/282,255

(22) Filed: Jul. 28, 2025

Related U.S. Application Data
(63) Continuation of application No. 18/524,445, filed on Nov. 30, 2023.
(60) Provisional application No. 63/510,727, filed on Jun. 28, 2023.

(51) Int. Cl. H10D 84/01; H01L 21/285; H01L 21/74; H01L 23/522; H01L 23/528; H10D 62/10; H10D 84/03

(52) U.S. Cl. CPC H10D 84/013; H01L 21/28518; H01L 21/743; H01L 23/5226; H01L 23/5286; H10D 84/0149; H10D 84/0151; H10D 84/038; H10D 62/121

(57) ABSTRACT

An exemplary device includes a frontside power rail disposed over a frontside of a substrate, a backside power rail disposed over a backside of the substrate, an epitaxial source/drain structure disposed between the frontside power rail and the backside power rail. The epitaxial source/drain structure is connected to the frontside power rail by a frontside source/drain contact. The epitaxial source/drain structure is connected to the backside power rail by a backside source/drain via. The backside source/drain via is disposed in a substrate, and a dielectric layer is disposed between the substrate and the backside power rail. The backside source/drain via extends through the dielectric layer and the substrate. A frontside silicide layer may be between the frontside source/drain contact and the epitaxial source/drain structure, and a backside silicide layer may be between the backside source/drain contact and the epitaxial source/drain structure, such that the epitaxial source/drain structure between silicide layers.

This is a continuation application of U.S. patent application Ser. No. 18/524,445, filed Nov. 30, 2023, which is a non-provisional application of and claims benefit of U.S. Provisional Patent Application Ser. No. 63/510,727, filed Jun. 28, 2023, the entire disclosures of which are incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, to enable further density reduction of advanced IC technology nodes, frontside interconnect structures and backside interconnect structures may be needed to facilitate electrical connection to and/or operation of IC devices. Although existing interconnect structures for facilitating electrical connection have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating a dual side interconnect structure for a device according to various aspects of the present disclosure.

FIGS. 2-15 are cross-sectional views of a device, in portion or entirety, at various fabrication stages associated with the method of FIG. 1 according to various aspects of the present disclosure.

### DETAILED DESCRIPTION

The present disclosure relates generally to dual-side interconnects for devices, such as multigate devices and/or stacked devices, and methods of fabrication thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

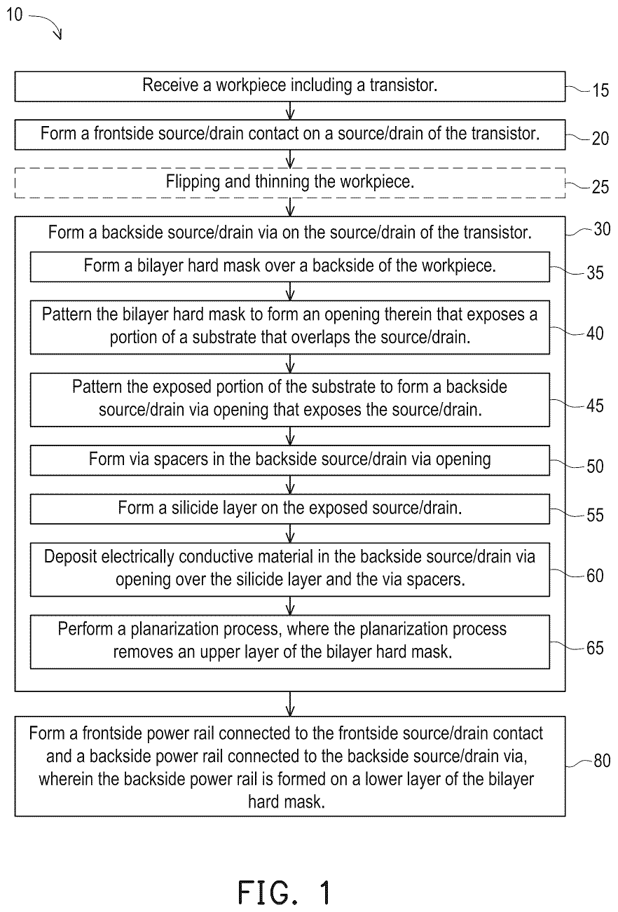

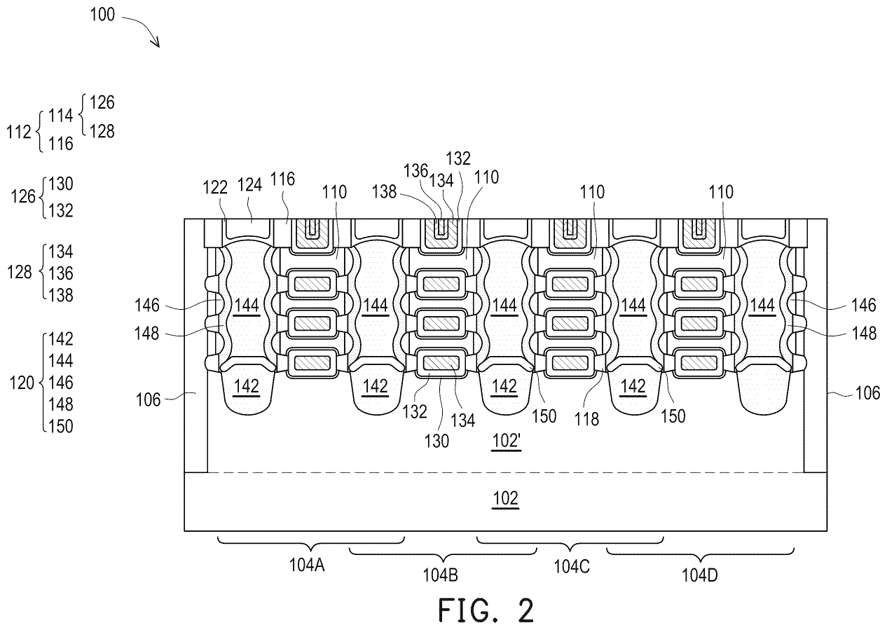

FIG. 1 is a flow chart of a method 10, in portion or entirety, for fabricating a dual side device-level interconnect structure for a device according to various aspects of the present disclosure. FIGS. 2-15 are cross-sectional views of a device 100, in portion or entirety, at various fabrication stages associated with method 10 of FIG. 1 according to various aspects of the present disclosure. Device 100 may be included in a microprocessor, a memory, other integrated circuit (IC) device, or a combination thereof. In some embodiments, device 100 is a portion of an IC chip, a system on chip (SoC), or portion thereof, that includes various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The various transistors may be planar transistors or non-planar transistors, such as fin-like FETs (FinFETs) or gate-all-around (GAA) transistors. FIG. 1 and FIGS. 2-15 are discussed concurrently herein for case of description and understanding. FIG. 1 and FIGS. 2-15 have been simplified for the sake of clarity to better understand the inventive concepts of the present disclosure. Additional steps can be provided before, during, and after method 10, and some of the steps described can be moved, replaced, or eliminated for additional embodiments of method 10. Additional features can be added in device 100 of FIGS. 2-15, and some of the features described below can be replaced, modified, or eliminated in other embodiments of device 100 of FIGS. 2-15.

Referring to FIG. 1 and FIG. 2, method 10 at block 15 includes receiving a workpiece (e.g., device 100) that has undergone FEOL processing, which may include forming electrically functional devices (e.g., a transistor 104A, a transistor 104B, a transistor 104C, and a transistor 104D) on a substrate (wafer) 102. Device 100 and/or the electrically functional devices include various features/components, such as a mesa 102′ (e.g., an extension of substrate 102), substrate isolation structures 106, semiconductor layers 110, gate structures 112 (each of which has a respective gate stack 114 and respective gate spacers 116), inner spacers 118, source/drains 120, and a first-level dielectric layer (e.g., an ILD0, which may include a contact etch stop layer (CESL) 122 and an interlayer dielectric (ILD) layer 124). The various features/components and their respective configurations is merely exemplary. The present disclosure contemplates device 100 having any combination of features/components and/or devices and any configuration of such features/components and/or devices that may be fabricated by FEOL processing.

In the depicted embodiment, transistors 104A-104D are GAA transistors. For example, each of transistors 104A-104D has three channels (e.g., nanowires, nanosheets, nanobars, etc.) provided by semiconductor layers 110, which are suspended over substrate 102 and extend between respective source/drains (e.g., source/drains 120). In some embodiments, transistors 104A-104D include more or less channels (and thus more or less semiconductor layers 110). Each of transistors 104A-104D also has a respective gate stack 114 over its semiconductor layers 110, engaging its semiconductor layers 110, and between its source/drains 120 (e.g., epitaxial source/drains). Along a gate widthwise direction (e.g., in X-Z cross-sectional views), gate stacks 114 are over top semiconductor layers 110, between semiconductor layers 110, and between bottom semiconductor layers 110 and substrate 102 (e.g., mesa 102′ thereof). Along a gate lengthwise direction (e.g., in Y-Z cross-sectional views), gate stacks 114 wrap and/or surround respective semiconductor layers 110. During operation of the GAA transistors, current can flow through semiconductor layers 110 and between source/drains 120.

Substrate 102 and semiconductor layers 110 include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 102 and semiconductor layers 110 include silicon. In some embodiments, substrate 102 is a semiconductor-on-insulator substrate, such as a silicon-on-insulator substrate, a silicon germanium-on-insulator substrate, or a germanium-on-insulator substrate. Substrate 102 (including mesas 102′ extending therefrom) may include various doped regions, such as p-wells and n-wells. The n-wells are doped with n-type dopant, such as phosphorus, arsenic, other n-type dopant, or a combination thereof. The p-wells are doped with p-type dopant, such as boron, indium, other p-type dopant, or a combination thereof. In some embodiments, semiconductor layers 110 include p-type dopant, n-type dopant, or a combination thereof.

Substrate isolation structures 106 electrically isolate active device regions and/or passive device regions. For example, substrate isolation structures 106 separate and electrically isolate active regions, such as transistors 104A-104D, from other device regions and/or devices. Substrate isolation structures 106 includes silicon oxide, silicon nitride, silicon oxynitride, other suitable isolation material (including, silicon, oxygen, nitrogen, carbon, other suitable isolation constituent, or a combination thereof), or a combination thereof. Substrate isolation structures 106 may have a multilayer structure. For example, substrate isolation structures 106 include a bulk dielectric (e.g., an oxide layer) over a dielectric liner (e.g., silicon nitride, silicon oxide, silicon oxynitride, silicon oxycarbonitride, or a combination thereof). In another example, substrate isolation structures 106 include a bulk dielectric over a doped liner, such as a boron silicate glass (BSG) liner and/or a phosphosilicate glass (PSG) liner. Dimensions and/or characteristics of substrate isolation structures 106 are configured to provide shallow trench isolation (STI) structures, deep trench isolation (DTI) structures, local oxidation of silicon (LOCOS) structures, other suitable isolation structures, or a combination hereof.

Gate stacks 114 are configured to achieve desired functionality according to design requirements of device 100, and gate stacks 114 of transistors 104A-104D may include the same or different layers and/or materials. Each gate stack includes a respective gate dielectric 126 and a respective gate electrode 128. Gate dielectrics 126 include at least one dielectric gate layer, and gate electrodes 128 include at least one electrically conductive gate layer. For example, gate dielectrics 126 may include an interfacial layer 130 and a high-k dielectric layer 132, and gate electrodes 128 may include a work function layer 134, a bulk (fill) layer 136, and an intermediate gate electrode layer 138. Interfacial layer 130 includes a dielectric material, such as SiO₂, SiGeOₓ, HfSiO, SiON, other dielectric material, or a combination thereof. High-k dielectric layer 132 includes a high-k dielectric material, which generally refers to dielectric materials having a dielectric constant that is greater than a dielectric constant of silicon dioxide (k≈3.9), such as HfO₂, HfSiO, HfSiO₄, HfSION, HfLaO, HfTaO, HITIO, HfZrO, HfAIOx, ZrO, ZrO₂, ZrSiO₂, AlO, AlSiO, Al₂O₃, TiO, TiO₂, LaO, LaSiO, LaO₃, La₂O₃, Ta₂O₃, Ta₂Os, Y₂O₃, SrTiO₃, BaZrO, BaTiO₃ (BTO), (Ba,Sr) TiO₃ (BST), Si₃N₄, HfO₂—Al₂O₃, other high-k dielectric material, or a combination thereof. Work function layer 134 is an electrically conductive layer tuned to have a desired work function, such as an n-type work function or a p-type work function. Work function layer 134 includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. Bulk layer 136 includes Al, W, Co, Cu, polysilicon, other suitable electrically conductive material, alloys thereof, or a combination thereof. Intermediate gate electrode layer 138 may include a cap (e.g., a metal nitride cap and/or a silicon cap over work function layer 134) and/or a barrier layer (e.g., a metal nitride barrier over the cap and/or work function layer 134). Intermediate gate electrode layer 138 may include a material that prevents or eliminates diffusion and/or reaction of constituents between adjacent layers and/or promotes adhesion between adjacent layers, such as between work function layer 134 and bulk layer 136. In some embodiments, intermediate gate electrode layer 138 includes metal and nitrogen, such as titanium nitride, tantalum nitride, tungsten nitride, titanium silicon nitride, tantalum silicon nitride, other suitable metal nitride, or a combination thereof. In some embodiments, gate stacks 114 further include hard masks over gate electrodes 128 and between gate spacers 116. Hard masks include a material that is different than the first-level dielectric layer to achieve etch selectivity during subsequent processing. In some embodiments, hard masks include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, hard masks include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or a combination thereof. In some embodiments, interfacial layer 130, high-k dielectric layer 132, work function layer 134, bulk layer 136, intermediate gate electrode layer 138, other gate stack layer, or a combination thereof has a multilayer structure.

Gate spacers 116 are disposed along sidewalls of top portions of gate stacks 114, fin/mesa spacers may be disposed along sidewalls of mesas 102′, and inner spacers 118 are disposed under gate spacers 116 along sidewalls of gate stacks 114. Inner spacers 118 are between semiconductor layers 110, between semiconductor layers 110 and mesa 102′, and between gate stacks 114 and source/drains 120. Gate spacers 116, fin/mesa spacers, and inner spacers 118 include a dielectric material. The dielectric material may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Gate spacers 116, fin/mesa spacers, and inner spacers 118 may include different materials and/or different configurations (e.g., different numbers of layers). In some embodiments, gate spacers 116, fin/mesa spacers, inner spacers 118, or a combination thereof have a multilayer structure. In some embodiments, gate spacers 116 and/or fin/mesa spacers include more than one set of spacers, such as seal spacers, offset spacers, sacrificial spacers, dummy spacers, main spacers, or a combination thereof. The various sets of spacers may have different compositions.

Source/drains 120 include semiconductor material, which may be doped with n-type dopants and/or p-type dopants. Source/drains 120 include multiple semiconductor layers and/or semiconductor materials, and each of the semiconductor layers/materials may include the same or different materials and/or the same or different dopant concentrations. In some embodiments, the semiconductor material is epitaxially grown from mesa 102′ and/or semiconductor layers 110, and source/drains 120 may be referred to as epitaxial source/drains. In some embodiments, source/drains 120 include silicon doped with carbon, phosphorous, arsenic, other n-type dopant, or a combination thereof (e.g., Si: C source/drains, Si: P source/drains, or Si: C: P source/drains). In some embodiments, source/drains 120 include silicon germanium or germanium, which is doped with boron, other p-type dopant, or a combination thereof (e.g., Si: Ge: B source/drains). Source/drains 120 may have the same or different compositions and/or materials depending on configurations of their respective transistors. For example, source/drains 120 of n-type transistors may include silicon doped with phosphorous and/or carbon, and source/drains 120 of p-type transistors may include silicon germanium doped with boron. In some embodiments, source/drains 120 include materials and/or dopants that achieve desired tensile stress and/or compressive stress in adjacent channel regions (e.g., semiconductor layers 110). As used herein, source/drain region, source/drain, source/drain feature, etc. may refer to a source of a device (e.g., a source of one of transistors 104A-104D), a drain of a device (e.g., a drain of one of transistors 104A-104D), or a source and/or a drain of multiple devices.

In some embodiments, source/drains 120 include multiple semiconductor layers and/or semiconductor materials, and each of the semiconductor layers/materials may include the same or different materials and/or the same or different dopant concentrations. For example, source/drains 120 may include semiconductor layers 142, semiconductor layers 144, semiconductor layers 146, and semiconductor layers 148. Semiconductor layers 142 are disposed in mesa 102′, semiconductor layers 144 are disposed over semiconductor layers 142, semiconductor layers 146 are disposed over semiconductor layers 110 (e.g., along sidewalls thereof), and semiconductor layers 148 are disposed between semiconductor layers 144 and semiconductor layers 146 and between semiconductor layers 144 and inner spacers 118. In some embodiments, semiconductor layers 142, semiconductor layers 144, semiconductor layers 146, and semiconductor layers 148 have different compositions. For example, semiconductor layers 142, semiconductor layers 144, semiconductor layers 146, and semiconductor layers 148 may include the same semiconductor material, but different dopant concentrations. In some embodiments, semiconductor layers 142 are undoped. Source/drains 120 may further include a source/drain isolation structure 150, which may be referred to as flexible bottom isolation (FBI). A composition of source/drain isolation structure 150 is different than a composition of semiconductor layers 142 and semiconductor layers 144 to facilitate selective etching during processing, as described further below. For example, source/drain isolation structures 150 include silicon and oxygen, nitrogen, carbon, or a combination thereof. In the depicted embodiment, source/drain isolation structures 150 are nitride layers, such as silicon nitride layers (e.g., SiNₓ layer). In some embodiments, a thickness of source/drain isolation structures 150 (e.g., along the z-direction) is about 1 nm to about 10 nm.

ILD layer 124 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, ILD layer 124 includes a dielectric material having a dielectric constant that is less than a dielectric constant of silicon dioxide. CESL 122 include a material different than a material of ILD layer 124. For example, where ILD layer 124 include a low-k dielectric material (e.g., porous silicon oxide), CESL 122 may include silicon and nitrogen and/or carbon, such as silicon nitride, silicon carbonitride, or silicon oxycarbonitride. In some embodiments, CESL 122 may include metal and oxygen, nitrogen, carbon, or a combination thereof. In some embodiments, ILD layer 124 and/or CESL 122 has a multilayer structure.

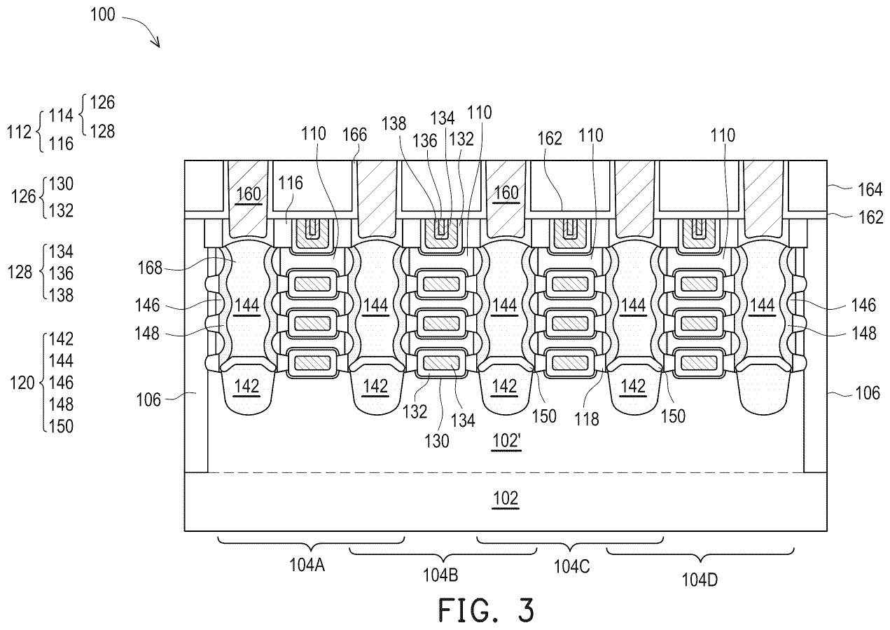

Referring to FIG. 1 and FIG. 3, method 10 at block 20 includes forming a frontside source/drain contact on a source/drain of a transistor, such as frontside source/drain contacts 160 on source/drains 120 of transistors 104A-104D. Frontside source/drain contacts 160 include an electrically conductive material, such as tungsten, ruthenium, cobalt, molybdenum, copper, aluminum, titanium, tantalum, iridium, palladium, platinum, nickel, tin, gold, silver, other suitable metal, alloys thereof, or a combination thereof. In some embodiments, frontside source/drain contacts 160 are barrier-free/liner-free metal plugs, such as tungsten plugs, cobalt plugs, or ruthenium plugs. For example, frontside source/drain contacts 160 may each include a metal bulk layer (i.e., a metal plug), such as a tungsten plug, that physically, directly contacts surrounding dielectric materials, such as contact spacers 166 and/or a second-level dielectric layer (e.g., a CESL 162 and/or an ILD layer 164). In some embodiments, frontside source/drain contacts 160 include metal bulk layers and one or more barrier/liner layers. The barrier/liner layers are between the metal bulk layers and surrounding dielectric materials.

Forming frontside source/drain contacts 160 may include depositing the second-level dielectric layer (e.g., an ILD1, which may include CESL 162 and ILD layer 164) over the first-level dielectric layer (e.g., ILD0, which may include CESL 122 and ILD layer 124), patterning the second-level dielectric layer and the first-level dielectric layer to form frontside source/drain contact openings extending therethrough that expose source/drains 120 (e.g., semiconductor layers 144 thereof), depositing electrically conductive material(s) over the second-level dielectric layer that fills the frontside source/drain contact openings, and performing a planarization process (e.g., chemical mechanical polishing (CMP)) to remove portions of the electrically conductive material(s) disposed over the second-level dielectric layer. CESL 162 and ILD layer 164 are similar to CESL 122 and ILD layer 124, described above. The planarization process may be performed until reaching and exposing the second-level dielectric layer, and remainders of the electrically conductive material(s) form one or more layers of frontside source/drain contacts 160. In some embodiments, before depositing the electrically conductive material(s), one or more insulation layers may be formed in the frontside source/drain contact openings and patterned to form contact spacers 166. Contact spacers 166 are disposed along sidewalls of frontside source/drain contacts 160 and contact spacers 166 are between frontside source/drain contacts 160 and surrounding dielectric material (e.g., the second-level dielectric layer and the first-level dielectric layer). Contact spacers 166 include dielectric layers and/or air gaps.

Before depositing the electrically conductive material(s), a silicidation process may be performed to form frontside silicide layers 168 over tops, fronts of source/drains 120, such that frontside silicide layers 168 are between tops of source/drains 120 (e.g., formed by semiconductor layers 144 and semiconductor layers 148 thereof) and frontside source/drain contacts 160. In embodiments where frontside source/drain contacts 160 include the barrier/liner layers, the barrier/liner layers may be between the metal bulk layers and frontside silicide layers 168. The silicidation process may include depositing a metal layer over source/drains 120 (e.g., semiconductor layers 144 and semiconductor layers 148 thereof) by a suitable deposition process and heating device 100 (for example, by subjecting it to an annealing process) to cause constituents of source/drains 120 to react with metal constituents in the metal layer. In some embodiments, the silicidation process consumes and converts portions of source/drains 120 into frontside silicide layers 168. The metal layer includes metal constituent suitable for promoting silicide formation, such as nickel, platinum, palladium, vanadium, titanium, cobalt, tantalum, ytterbium, zirconium, other suitable metal, or a combination thereof. Frontside silicide layers 168 may thus include a metal constituent and a constituent of source/drains 120 (for example, silicon and/or germanium). In some embodiments, the metal layer is a titanium-containing layer, and frontside silicide layers 168 include titanium and silicon and/or germanium. In some embodiments, the metal layer is a cobalt-containing layer, and frontside silicide layers 168 include cobalt and silicon and/or germanium. In some embodiments, the metal layer is a nickel-containing layer, and frontside silicide layers 168 include nickel and silicon and/or germanium. Any un-reacted metal is selectively removed by a suitable process.

In some embodiments, before depositing the electrically conductive material(s), an etching process is performed to extend the frontside source/drain contact openings into source/drains 120 and below top surfaces of top semiconductor layers 110. Such process may be referred to as a source/drain etch back and/or a source/drain recess. After recessing, the frontside source/drain contact openings extend a distance below the first-level dielectric layer and/or the tops surfaces of top semiconductor layers 110. The distance is between bottoms of the frontside source/drain contact openings and tops of top semiconductor layers 110 (and/or bottoms of the first-level dielectric layer). Further, after recessing, source/drains 120 may have dished, concave top surfaces that form bottoms of the frontside source/drain contact openings. In the depicted embodiment, the dished, concave top surfaces are formed by semiconductor layers 144 and semiconductor layers 148, and frontside silicide layers 168 are formed on and conform to the dished, concave top surfaces, such that frontside silicide layers 168 have curvilinear, concave profiles. The source/drain recess increases a contact area between tops, fronts of source/drains 120 and frontside source/drain contacts 160, which may reduce contact resistance (such as that arising between source/drains (epi) and frontside source/drain contacts (MD) (e.g., epi-to-MD contact resistance)) and thereby improve performance of device 100.

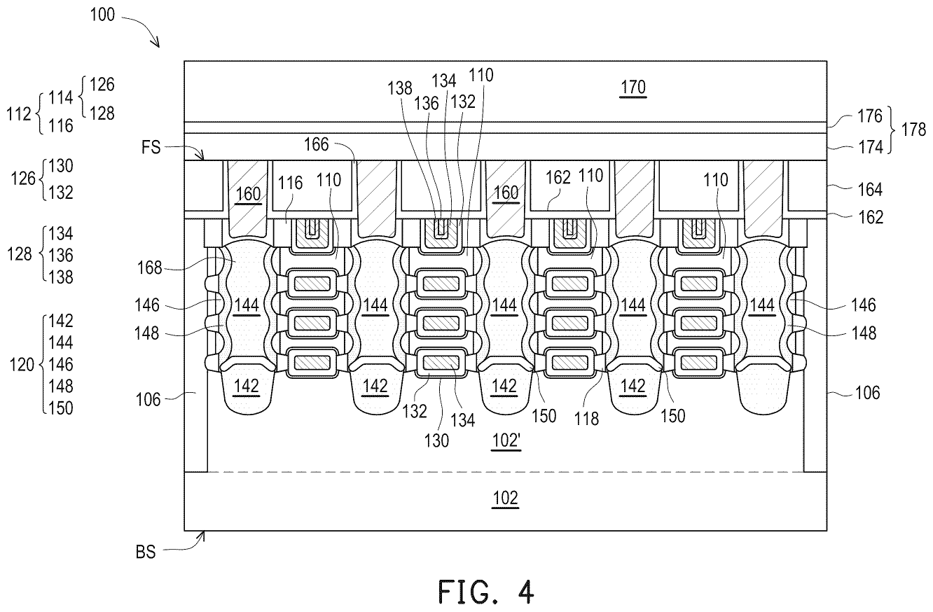

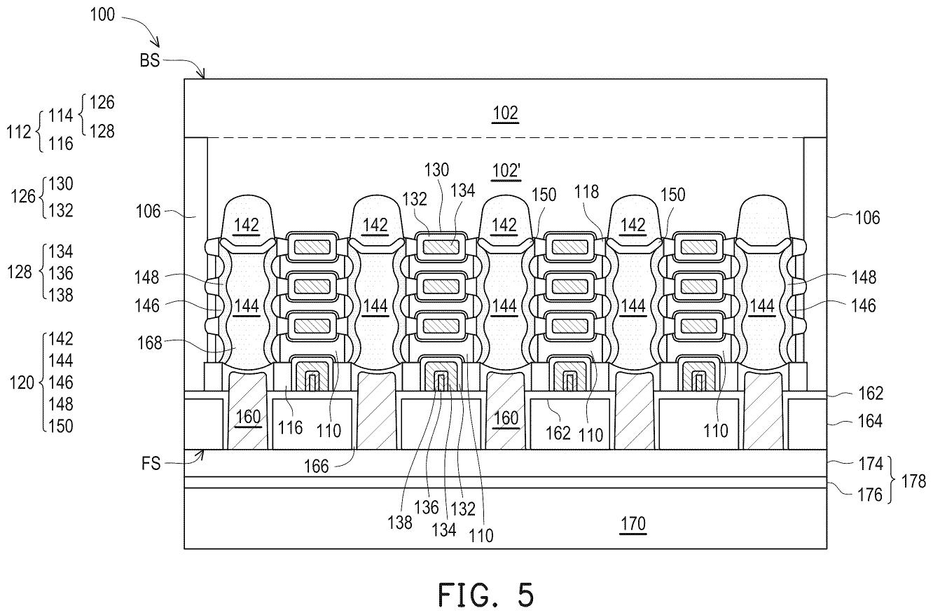

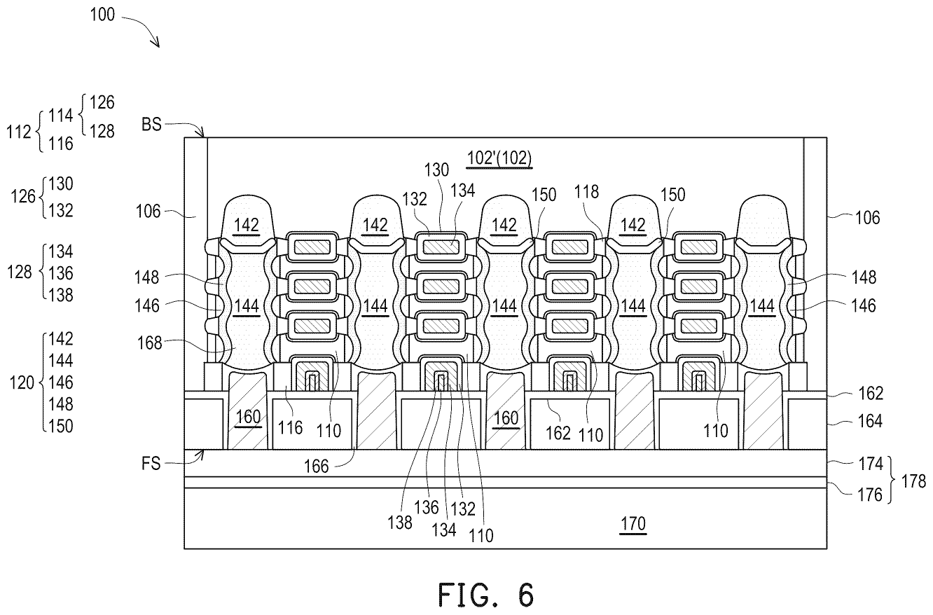

Referring to FIG. 1 and FIGS. 4-6, method 10 at block 25 may include flipping and thinning the workpiece (e.g., device 100). Referring to FIG. 4, the flipping/thinning may include bonding and/or attaching a carrier substrate 170 to a frontside FS of device 100, which is formed by frontside source/drain contacts 160 and the second-level dielectric layer. Referring to FIG. 5, the flipping/thinning may include flipping over device 100, such that backside BS of device 100 is oriented up, frontside FS of device 100 is oriented down, and carrier substrate 170 forms a bottom of device 100. Referring to FIG. 6, the flipping/thinning may include performing a thinning process to reduce a thickness of substrate 102 (e.g., along the z-direction). The thinning process is applied to backside BS of device 100, and in the depicted embodiment, the thinning process reduces a thickness of substrate 102 over source/drains 120. In some embodiments, extensions of substrate 102 (i.e., mesa 102′) remain after the thinning process. The thinning process may be a grinding process, a planarization process (e.g., CMP), an etching process, other suitable process, or a combination thereof. In some embodiments, the thinning process stops upon reaching substrate isolation structures 106. In some embodiments, the thinning process may reduce a thickness of substrate isolation structures 106 (e.g., along the z-direction).

In FIG. 4, the bonding may include forming a bonding layer 174 (e.g., a first dielectric layer) over frontside FS of device 100, forming a bonding layer 176 (e.g., a second dielectric layer) over carrier substrate 170, flipping over and placing carrier substrate 170 over frontside FS of device 100, such that bonding layer 176 contacts bonding layer 174, and performing an anneal process and/or other suitable process to effectuate bonding of bonding layer 174 and bonding layer 176. In such embodiments, bonding layer 174 and/or a portion thereof, bonding layer 176 and/or a portion thereof, a bonded portion of bonding layer 174 and bonding layer 176, or a combination thereof may form a bonding layer 178 between carrier substrate 170 and frontside FS of device 100. In some embodiments, the bonding is dielectric-to-dielectric bonding. In such embodiments, the bonding layer 178, bonding layer 176, and bonding layer 174 are dielectric layers, and the dielectric layers may include silicon, oxygen, nitrogen, carbon, other suitable dielectric constituent, or a combination thereof. For example, bonding layer 176 and bonding layer 174 may be nitride layers, such as silicon nitride layers. In another example, bonding layer 176 and bonding layer 174 may be oxide layers. In some embodiments, carrier substrate 170 includes silicon, soda-lime glass, fused silica, fused quartz, calcium fluoride, other suitable carrier substrate material, or a combination thereof.

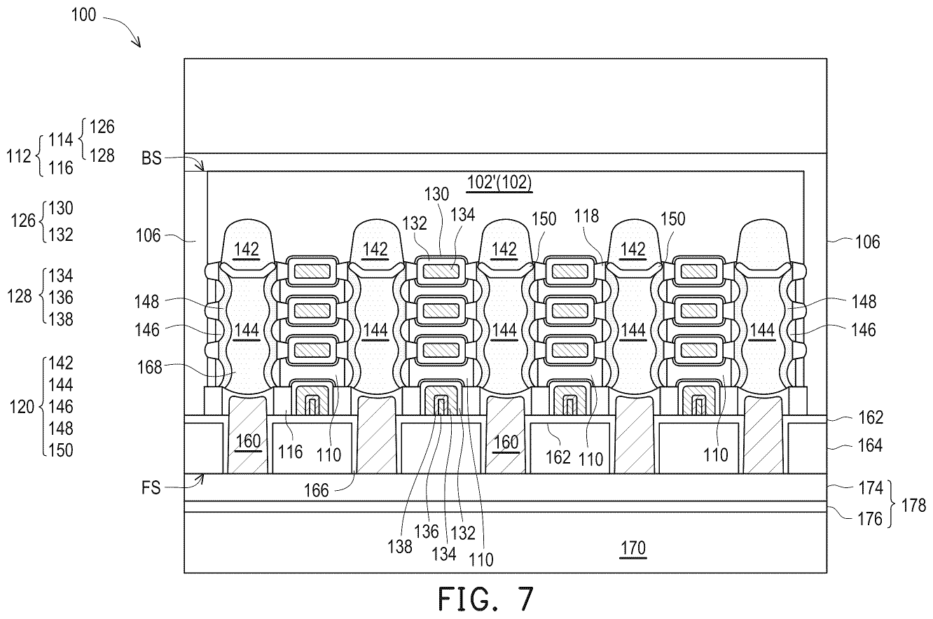

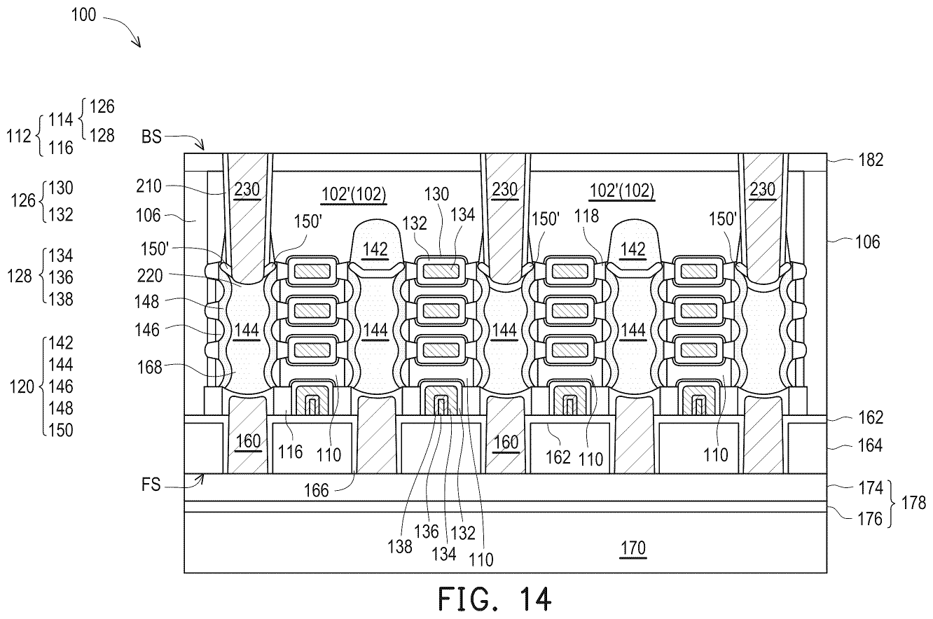

Referring to FIG. 1 and FIGS. 7-14, method 10 at block 30 includes forming a backside source/drain via on a source/drain of the transistor, such as backside source/drain vias 230 on bottoms, backs of source/drains 120 of transistors 104A-104D (FIG. 14). Processing involved with forming backside source/drain vias 230 is performed on backside BS of device 100. Referring to FIG. 1 and FIG. 7, method 10 at block 35 includes forming a bilayer hard mask over a backside of the workpiece, such as a bilayer hard mask 180 over backside BS of device 100, which is formed by substrate 102 (e.g., mesa 102′ thereof) and substrate isolation structures 106. Bilayer hard mask 180 includes a hard mask layer 182 and a hard mask layer 184. Hard mask layer 182 is disposed on backside BS of device 100, and hard mask layer 184 is disposed on hard mask layer 182. A thickness of hard mask layer 182 is less than a thickness of hard mask layer 184. In some embodiments, a thickness of hard mask layer 182 is about 5 nm to about 30 nm. In some embodiments, a thickness of hard mask layer 184 is about 10 nm to about 100 nm. Hard mask layer 182 and hard mask layer 184 are formed by chemical vapor deposition (CVD), atomic layer deposition (ALD), other suitable process, or a combination thereof. Hard mask layer 182 and hard mask layer 184 may be formed by a same type of deposition process or different types of deposition processes. In some embodiments, hard mask layer 182 is a furnace deposited layer. In some embodiments, hard mask layer 184 is a furnace deposited layer.

A composition of hard mask layer 182 is different than a composition of hard mask layer 184 to enable selective removal/etching/polishing thereof (e.g., enable removal of hard mask layer 184 with no (or negligible) removal of hard mask layer 182). Further, because (1) bilayer hard mask 180 will function as a mask for patterning (e.g., etching) substrate 102 and (2) hard mask layer 182 will electrically isolate a backside of substrate 102 from a subsequently formed backside routing layer(s), the composition of hard mask layer 184 is different than a composition of substrate 102, and the composition of hard mask layer 182 is different than a composition of substrate 102. In some embodiments, hard mask layer 182 and hard mask layer 184 each include silicon and oxygen, nitrogen, carbon, or a combination thereof. For example, hard mask layer 182 may be a silicon nitride layer (e.g., an SiNₓ layer), and hard mask layer 184 may be a silicon oxide layer (e.g., an SiO_{y} layer). In such embodiments, hard mask layer 184 and hard mask layer 182 may be referred to as dielectric layers. In some embodiments, hard mask layer 182 and hard mask layer 184 have any combination of compositions that accomplish the patterning functions, etch/polishing stop functions, and isolation functions thereof, as described herein.

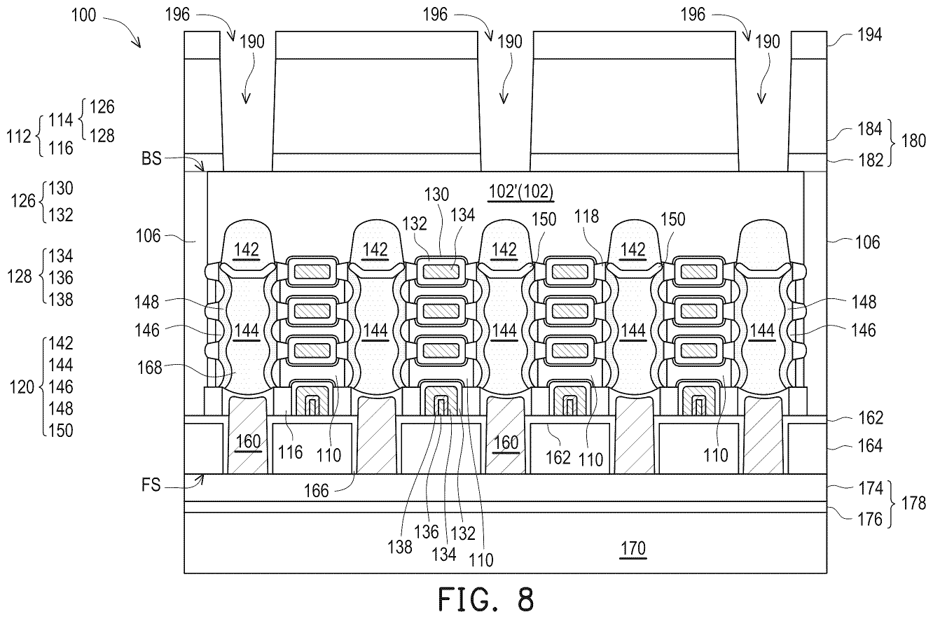

Referring to FIG. 1 and FIG. 8, method 10 at block 40 includes patterning the bilayer hard mask to form an opening therein that exposes a portion of a substrate that overlaps the source/drain. For example, bilayer hard mask 180 is patterned to form openings 190 therein that expose portions of substrate 102 that overlap source/drains 120. Openings 190 extend through hard mask layer 184 and hard mask layer 182 to expose substrate 102. Block 40 of method 10 may be referred to as a hard mask patterning step and/or a hard mask (HM) etch step.

Bilayer hard mask 180 may be patterned by a lithography process and an etching process. The lithography process may include forming a patterned mask layer 194 over hard mask layer 184. Patterned mask layer 194 has openings 196 therein, each of which overlaps a backside of a respective one of source/drains 120. The etching process may include transferring a pattern in patterned mask layer 194 to bilayer hard mask 180, for example, by removing portions of hard mask layer 184 and hard mask layer 182 exposed by openings 196. The etching process may selectively remove bilayer hard mask 180 with respect to substrate 102. For example, the etching process etches bilayer hard mask 180 with no (or negligible) etching of substrate 102. An etchant of the etching process may etch dielectric material (e.g., hard mask layer 184 and hard mask layer 182) at a higher rate than semiconductor material (e.g., substrate 102). The etching process is a dry etch, a wet etch, other suitable etching process, or a combination thereof. In some embodiments, hard mask layer 184 and hard mask layer 182 are removed in a multistep process, such as a first etching process that selectively removes hard mask layer 184 with no (or negligible) etching of hard mask layer 182 and a second etching process that selectively removes hard mask layer 182 with no (or negligible) etching of substrate 102. For example, different etchants and/or etch parameters may be implemented to separately etch hard mask layer 184 and hard mask layer 182. In such embodiments, the first etching process may partially remove hard mask layer 184, or the first etching process may not (or negligibly) remove hard mask layer 184. In some embodiments, the etching process removes patterned mask layer 194, in portion or entirety, from over bilayer hard mask 180. In some embodiments, after the etching process, patterned mask layer 194 is removed from over bilayer hard mask 180, for example, by an etching process and/or a resist stripping process.

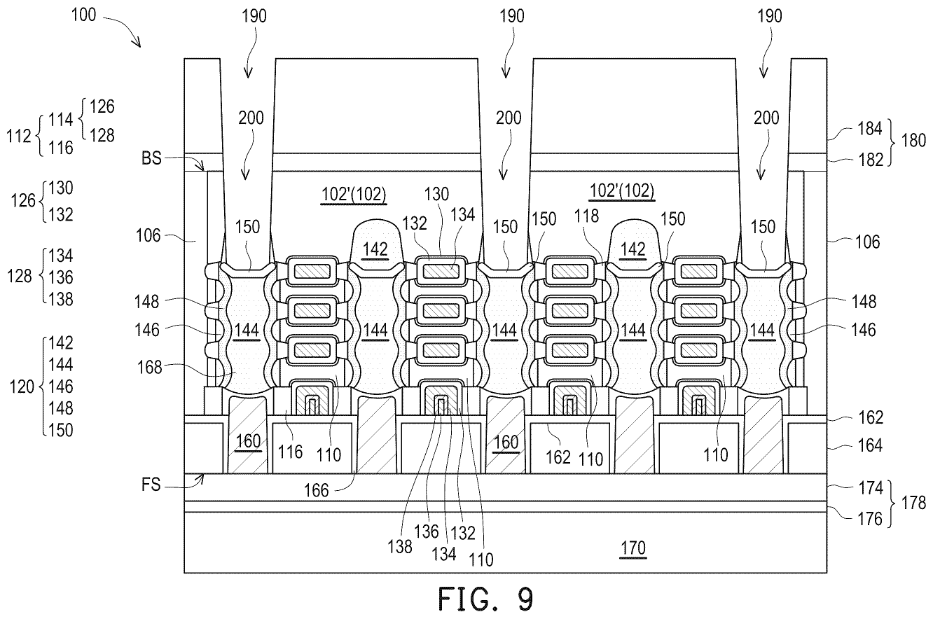

Referring to FIG. 1 and FIG. 9, method 10 at block 45 includes patterning the exposed portion of the substrate to form a backside source/drain via opening that exposes the source/drain. For example, exposed portions of substrate 102 are patterned to form backside source/drain via openings 200 therein that expose backsides of respective source/drains 120. After patterning substrate 102, backside source/drain via openings 200 extend through substrate 102 to expose source/drains 120, such as semiconductor layers 142 thereof. In the depicted embodiment, method 10 at block 45 further includes extending backside source/drain via openings 200 by removing portions of exposed source/drains 120, such as semiconductor layers 142 thereof. Removing semiconductor layers 142 exposes source/drain isolation structures 150 of source/drains 120 and extends backside source/drain via openings 200 above bottoms of gate stacks 114 and/or tops of mesa 102′. Block 45 of method 10 may be referred to as a substrate patterning and/or etch step and/or a source/drain via (VB) patterning and/or etch step.

Substrate 102 and source/drains 120 may be patterned by an etching process. The etching process may include transferring a pattern in bilayer hard mask 180 to substrate 102, for example, by removing portions of substrate 102 exposed by openings 190. The etching process may further include removing semiconductor layers 142 exposed by backside source/drain via openings 200. The etching process may selectively remove substrate 102 and semiconductor layers 142 with respect to bilayer hard mask 180 and source/drain isolation structures 150. For example, the etching process etches substrate 102 and/or semiconductor layers 142 with no (or negligible) etching of bilayer hard mask 180 and/or source/drain isolation structures 150. An etchant of the etching process may etch semiconductor material (e.g., substrate 102 and semiconductor layers 142) at a higher rate than dielectric material (e.g., bilayer hard mask 180 and source/drain isolation structures 150). Source/drain isolation structures 150 function as etch stop layers and etching of substrate 102 and/or semiconductor layers 142 may stop upon reaching source/drain isolation structures 150. The etching process is a dry etch, a wet etch, other suitable etching process, or a combination thereof. In some embodiments, substrate 102 and semiconductor layers 142 are removed in a multistep process, such as a first etching process that selectively removes substrate 102 with no (or negligible) etching of bilayer hard mask 180 and source/drains 120 (e.g., semiconductor layers 142 thereof) and a second etching process that selectively removes semiconductor layers 142 with no (or negligible) etching of source/drain isolation structures 150. For example, different etchants and/or etch parameters may be implemented to separately etch substrate 102 and semiconductor layers 142.

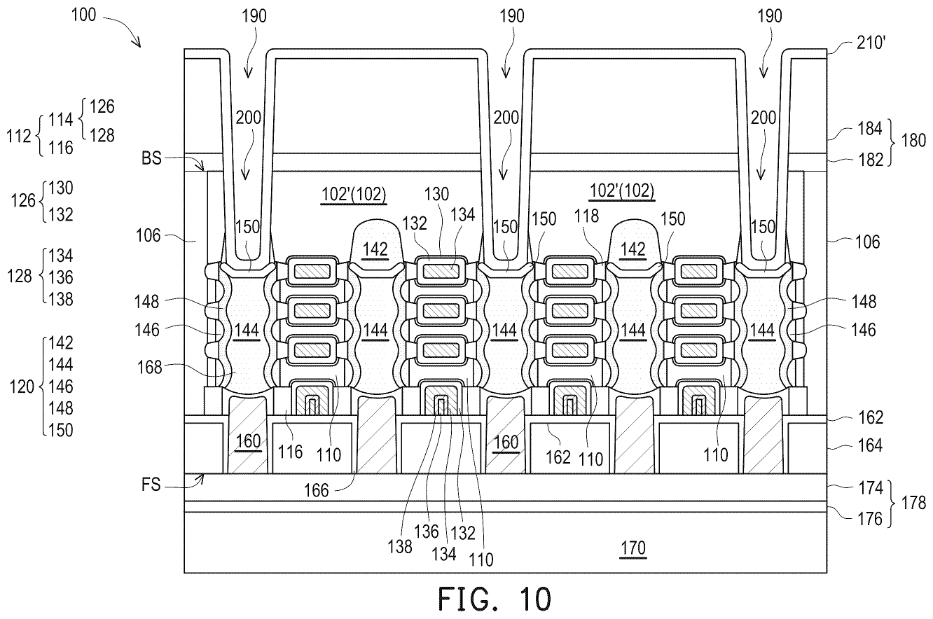

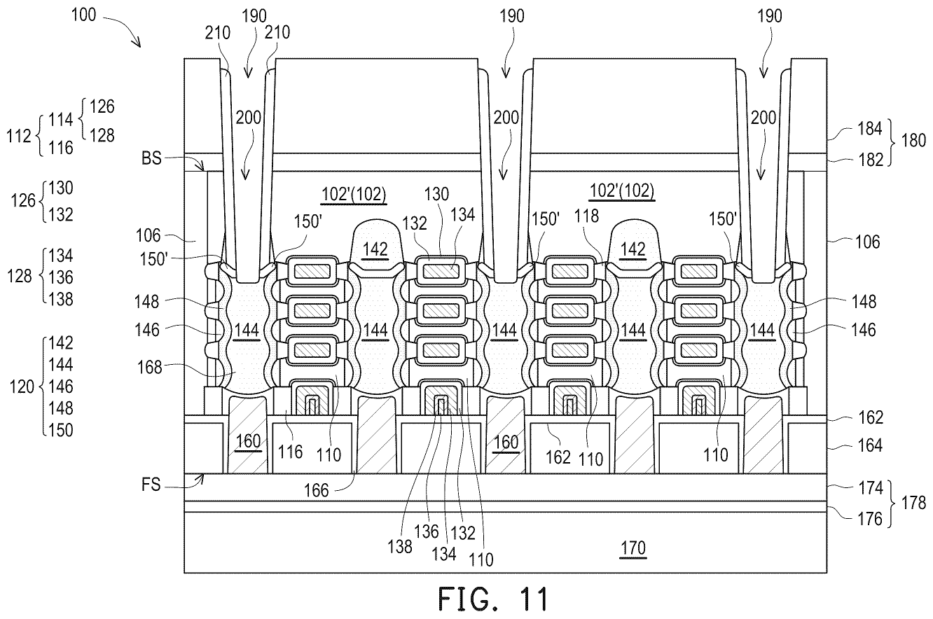

Referring to FIG. 1, FIG. 10, and FIG. 11, method 10 at block 50 includes forming via spacers in the backside source/drain via opening. For example, via spacers 210 are formed in backside source/drain via openings 200. Via spacers 210 may electrically isolate subsequently formed backside source/drain vias from substrate 102 and/or gate stacks 114, which inhibits and/or prevents electrical coupling of the subsequently formed backside source/drain vias with one another and/or with gate stacks 114. Referring to FIG. 10, forming via spacers 210 may include forming a via spacer layer 210′ over bilayer hard mask 180, such as over hard mask layer 184 thereof. Via spacer layer 210′ lines and partially fills backside source/drain via openings 200 in substrate 102. Via spacer layer 210′ further lines and partially fills openings 190 in bilayer hard mask 180. In the depicted embodiment, via spacer layer 210′ is disposed directly on a top surface of hard mask layer 184, sidewalls of backside source/drain via openings 200 (e.g., formed by substrate 102), sidewalls of openings 190 (e.g., formed by bilayer hard mask 180), and bottoms of backside source/drain via openings 200 (e.g., formed by source/drain isolation structures 150). Via spacer layer 210′ is formed by CVD, ALD, other suitable process, or a combination thereof. In some embodiments, via spacer layer 210′ is a furnace deposited layer. In some embodiments, via spacer layer 210′ is conformally deposited, such that via spacer layer 210′ has a substantially uniform thickness over the various surfaces of device 100. In some embodiments, a thickness of via spacer layer 210′ is about 1 nm to about 10 nm.

A composition of via spacer layer 210′ is different than a composition of hard mask layer 184 to enable selective etching/removal thereof, and via spacer layer 210′ includes an electrically insulating material. For example, via spacer layer 210′ includes a dielectric material that is different than the dielectric material of hard mask layer 184. The dielectric material includes silicon and oxygen, nitrogen, carbon, or a combination thereof (e.g., silicon oxide, silicon nitride, silicon oxynitride, silicon carbide, silicon oxycarbonitride, other suitable dielectric material, or a combination thereof). In some embodiments, such as depicted, via spacer layer 210′ includes the same material as substrate isolation structures 150. For example, via spacer layer 210′ includes silicon and nitrogen, such as silicon nitride or silicon oxynitride. In such embodiments, via spacer layer 210′ may be referred to as a nitride layer, and the process of forming via spacers 210 may be referred to as a backside self-protected nitride redeposition (BSNR) deposition (DP) and etch (ET) step. In some embodiments, via spacer layer 210′ and substrate isolation structures 150 include different materials and/or different compositions.

Referring to FIG. 11, an etching process extends backside source/drain via openings 200 through source/drain isolation structures 150 and exposes semiconductor layers 144 of source/drains 120, thereby forming source/drain isolation structure remnants 150′. The etching process further removes portions of via spacer layer 210′. For example, the etching process removes laterally oriented portions of via spacer layer 210′, such as portions of via spacer layer 210′ over hard mask layer 184 and over semiconductor layers 144. Remainders of via spacer layer 210′ provide via spacers 210 along sidewalls of backside source/drain via openings 200 and along sidewalls of openings 190 in bilayer hard mask 180. The etching process may reduce a thickness of via spacer layer 210′, such that a thickness of via spacers 210 is less than a thickness of via spacer layer 210′. In some embodiments, a thickness of via spacers 210 (e.g., along the x-direction and/or the y-direction) is about 1 nm to about 10 nm. Because backside source/drain via openings 200 are initially formed to source/drain isolation structures 150, source/drain isolation structure remnants 150′ are between via spacers 210 and semiconductor portions of source/drains 120 (e.g., semiconductor layers 144 and semiconductor layers 148 thereof). In the depicted embodiment, after the etching process, backside source/drain via openings 200 have sidewalls formed by via spacers 210 and source/drain isolation structure remnants 150′ and bottoms formed by semiconductor layers 144. Further, semiconductor layers 144 of exposed source/drains 120 forming the bottoms of extended backside source/drain via openings 200 may have dished, concave surfaces, which will provide source/drains 120 with dished, convex bottom surfaces when device 100 is oriented upright (i.e., backside BS thereof is oriented down and frontside FS thereof is oriented up). Recessing backsides of source/drains 120 will increase a contact area between bottoms, backs of source/drains 120 and the subsequently formed backside source/drain vias, which may reduce contact resistance (such as that arising between source/drains (epi) and backside source/drain vias (VB) (e.g., epi-to-VB contact resistance)) and thereby improve performance of device 100.

The etching process may selectively remove via spacer layer 210′ and source/drain isolation structures 150 with respect to hard mask layer 184 and semiconductor layers 144. For example, the etching process etches via spacer layer 210′ and source/drain isolation structures 150 with no (or negligible) etching of hard mask layer 184 and semiconductor layers 144. An etchant of the etching process may etch dielectric material having a first composition (e.g., via spacer layer 210′ and source/drain isolation structures 150) at a higher rate than dielectric material having a second composition (e.g., hard mask layer 184) and semiconductor material (e.g., semiconductor layers 144). The etching process is a dry etch, a wet etch, other suitable etching process, or a combination thereof. In some embodiments, the etching process is a reactive ion etch (RIE). In some embodiments, where via spacer layer 210′ and source/drain isolation structures 150 are nitride layers (e.g., silicon nitride layers) and hard mask layer 184 is an oxide layer (e.g., a silicon oxide layer), an etchant may selectively etch nitride without (or negligibly) etching oxide. In such embodiments, the etching process may remove portions of via spacer layer 210′ over hard mask layer 184 and a portion of via spacer layer 210′ over source/drain isolation structures 150, thereby exposing source/drain isolation structures 150. The etching process continues with removing the exposed source/drain isolation structures 150 until reaching and/or exposing semiconductor layers 144. In some embodiments, the etching process may further extend backside source/drain via openings 200 by removing and/or recessing semiconductor layers 144. In some embodiments, an etchant for recessing semiconductor layers 144 is different than an etchant used for etching via spacer layer 210′ and source/drain isolation structures 150. In some embodiments, an etchant for recessing semiconductor layers 144 is the same as an etchant used for etching via spacer layer 210′ and source/drain isolation structures 150. For example, the etchant may selectively etch nitride (e.g., via spacer layer 210′ and source/drain isolation structures 150) and silicon (or silicon germanium) (e.g., semiconductor layers 144) without (or minimally) etching oxide (e.g., hard mask layer 184). In such embodiments, the etchant may exhibit an etching selectivity between nitride and silicon (or silicon germanium) that achieves a desired removal of semiconductor layers 144. Further, in such embodiments, parameters of the etching process (e.g., etch duration, etch temperature, etc.) may be tuned to achieve desired recessing of semiconductor layers 144 and desired removal of via spacer layer 210′ and source/drain isolation structures 150.

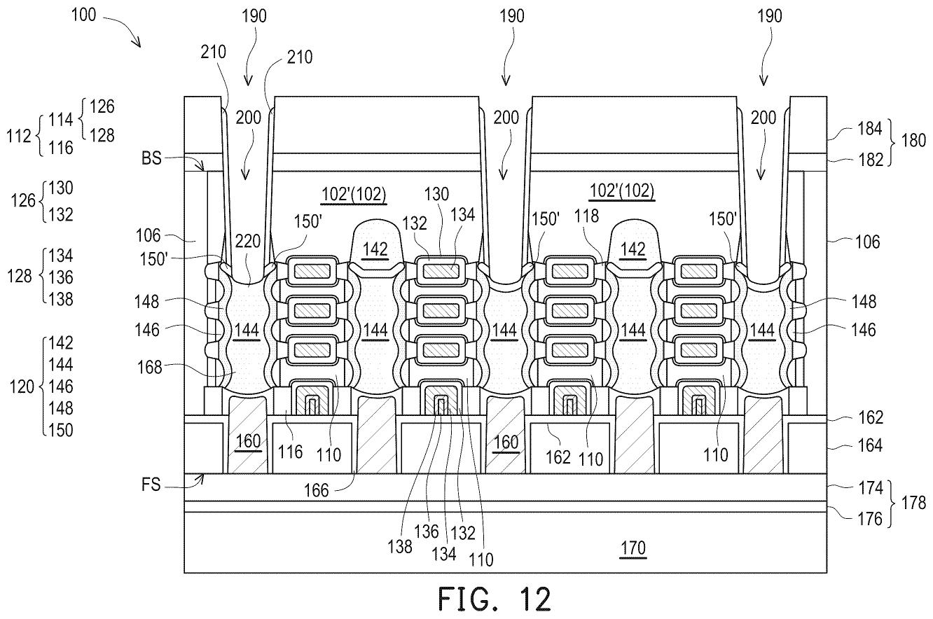

Referring to FIG. 1 and FIG. 12, method 10 at block 55 includes forming a silicide layer on the exposed source/drain. For example, a silicidation process may be performed to form backside silicide layers 220 over bottoms, backs of exposed source/drains 120, which may be formed by semiconductor layers 144 thereof. In the depicted embodiment, backside silicide layers 220 are formed on and conform to the dished, convex surfaces of exposed source/drains 120, such that backside silicide layers 220 have curvilinear, convex profiles when device 100 is oriented upright (i.e., backside BS thereof is oriented down and frontside FS thereof is oriented up). Some source/drains 120 are thus sandwiched between backside silicide layers 220 and frontside silicide layers 168. Because backside source/drain via openings 200 are extended above gate stacks 114 and/or tops of mesa 102′, backside silicide layers 220 are disposed above source/drain isolation structure remnants 150′ and via spacers 210 when device 100 is oriented upright. In the depicted embodiment, each backside silicide layer 220 is disposed on a respective semiconductor layer 144, between respective semiconductor layers 148, and between respective source/drain isolation structure remnants 150′. In some embodiments, a thickness of backside silicide layers 220 (e.g., along the z-direction) is about 1 nm to about 20 nm. In some embodiments, a thickness of backside silicide layers 220 is substantially uniform.

The silicidation process may include depositing a metal layer over hard mask layer 184, via spacers 210, source/drain isolation structure remnants 150′, and exposed source/drains 120 (e.g., semiconductor layers 144 thereof) by a suitable deposition process and heating device 100 (for example, by subjecting it to an annealing process) to cause constituents of source/drains 120 to react with metal constituents in the metal layer. The metal layer at least partially fills backside source/drain via openings 200. In some embodiments, the deposition process is CVD. In some embodiments, the metal layer is a furnace deposited layer. In some embodiments, the metal layer is a sputter deposited layer. In some embodiments, the silicidation process consumes and converts portions of source/drains 120 (e.g., semiconductor layers 144 thereof) into backside silicide layers 220. The metal layer includes metal constituent suitable for promoting silicide formation, such as nickel, platinum, palladium, vanadium, titanium, cobalt, tantalum, ytterbium, zirconium, other suitable metal, or a combination thereof. Backside silicide layers 220 may thus include a metal constituent and a constituent of source/drains 120 (for example, silicon and/or germanium). In some embodiments, the metal layer is a titanium-containing layer, and backside silicide layers 220 include titanium and silicon and/or germanium. In some embodiments, the metal layer is a cobalt-containing layer, and backside silicide layers 220 include cobalt and silicon and/or germanium. In some embodiments, the metal layer is a nickel-containing layer, and backside silicide layers 220 include nickel and silicon and/or germanium.

Any un-reacted metal is selectively removed by a suitable process. In some embodiments, an etching process selectively removes the metal layer and/or un-reacted metal with respect to hard mask layer 184, via spacers 210, and source/drain isolation structure remnants 150′. For example, the etching process etches the metal layer with no (or negligible) etching of hard mask layer 184, via spacers 210, source/drain isolation structure remnants 150′, and backside silicide layers 220. An etchant of the etching process may etch metal material (e.g., the metal layer) at a higher rate than dielectric material (e.g., hard mask layer 184, via spacers 210, and source/drain isolation structure remnants 150′) and metal-and-semiconductor material (e.g., backside silicide layers 220). The etching process is a dry etch, a wet etch, other suitable etching process, or a combination thereof. In some embodiments, such as depicted, the etching process may be tuned to selectively etch the metal layer but may partially and/or negligibly etch hard mask layer 184, via spacers 210, source/drain isolation structure remnants 150′, or a combination thereof. In such embodiments, a thickness of via spacers 210 (e.g., along the x-direction and/or the y-direction) and/or a thickness of hard mask layer 184 (e.g., along the z-direction) may be reduced by the etching process. Accordingly, a thickness of via spacers 210 after forming backside silicide layers 220 may be less than a thickness of via spacers 210 before forming backside silicide layers 220 and/or a thickness of hard mask layer 184 after forming backside silicide layers 220 may be less than a thickness of hard mask layer 184 before forming backside silicide layers 220. Further, a length of via spacers 210 (e.g., along the z-direction) may be reduced when forming backside silicide layers 220. In some embodiments, such as depicted, portions of via spacers 210 are removed from along sidewalls of hard mask layer 184 that form openings 190. In some embodiments, a width and/or a length of source/drain isolation structure remnants 150′ (e.g., along the x-direction and/or the y-direction) may also be reduced by the etching process. A width/length of source/drain isolation structure remnants 150′ after forming backside silicide layers 220 may thus be less than a width/length of source/drain isolation structure remnants 150′ before forming backside silicide layers 220.

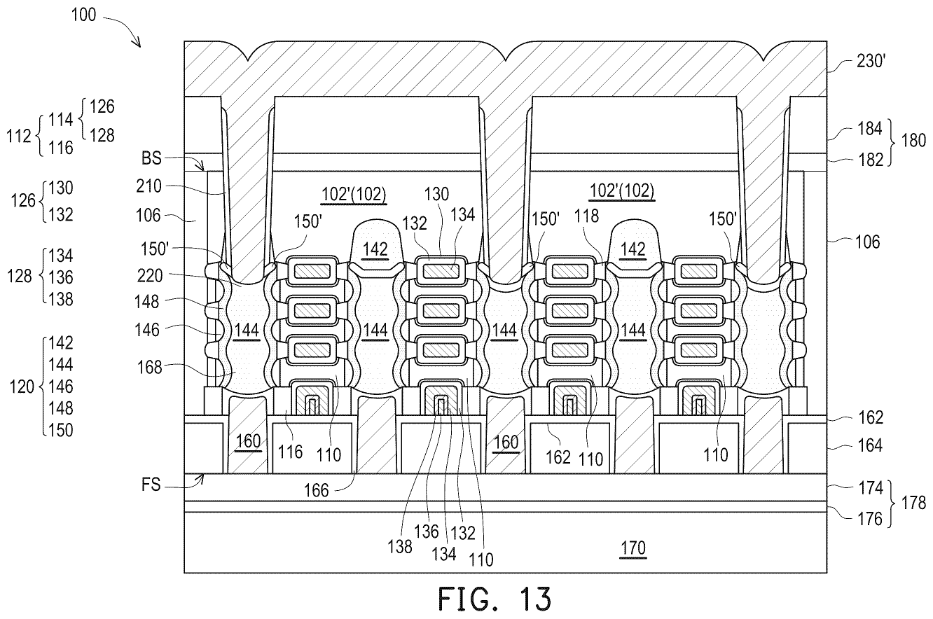

Referring to FIG. 1, FIG. 13, and FIG. 14, method 10 at block 60 and block 65 includes forming backside source/drain vias 230. Backside source/drain vias 230 are formed in backside source/drain via openings 200 and openings 190, such that backside source/drain vias 230 extend through hard mask layer 182, through substrate 102 (e.g., mesa 102′ thereof), and to bottoms, backs of source/drains 120 (e.g., formed by semiconductor layers 144 thereof). In the depicted embodiment, backside silicide layers 220 are between backside source/drain vias 230 and bottoms of source/drains 120. Backside source/drain vias 230 include tungsten, ruthenium, cobalt, molybdenum, copper, aluminum, titanium, tantalum, iridium, palladium, platinum, nickel, tin, gold, silver, other suitable metal, alloys thereof, or a combination thereof. In the depicted embodiment, backside source/drain vias 230 are barrier-free metal plugs. For example, backside source/drain vias 230 include metal bulk layers, such as tungsten plugs or cobalt plugs, that physically, directly contact surrounding dielectric materials, such as via spacers 210, source/drain isolation structure remnants 150′, hard mask layer 182, or a combination thereof. In some embodiments, one or more of backside source/drain vias 230 include a metal bulk layer and a metal liner, where the metal liner is between the metal bulk layer and surrounding dielectric materials. In such embodiments, the metal liner may be between the metal bulk layer and backside silicide layers 220. In some embodiments, a thickness of backside source/drain vias 230 (e.g., along the z-direction) is about 100 nm to about 500 nm.

Referring to FIG. 1 and FIG. 13, method 10 at block 60 includes depositing electrically conductive material (e.g., source/drain via material 230′) in the backside source/drain via opening (e.g., backside source/drain via openings 200) over the silicide layer (e.g., backside silicide layers 220) and the via spacers (e.g., via spacers 210). Source/drain via material 230′ is formed over hard mask layer 184, fills backside source/drain via openings 200, and fills openings 190 in bilayer hard mask 180. Source/drain via material 230′ includes tungsten, ruthenium, cobalt, molybdenum, copper, aluminum, titanium, tantalum, iridium, palladium, platinum, nickel, tin, gold, silver, other suitable metal, alloys thereof, or a combination thereof. Source/drain via material 230′ is formed by physical vapor deposition (PVD), CVD, ALD, sputter deposition, electroplating, electroless plating, other suitable deposition process, or a combination thereof. In the depicted embodiment, source/drain via material 230′ (e.g., tungsten or cobalt) is formed by a blanket deposition process (e.g., blanket CVD or blanket PVD), which may include flowing a metal-containing precursor (e.g., a tungsten-containing precursor, such as WF₆ and/or WCl₅, or a cobalt-containing precursor) and a reactant precursor (e.g., H₂, other suitable reactant gas, or a combination thereof) into a process chamber. A carrier gas may be used to deliver the metal-containing precursor gas and/or the reactant gas to the process chamber. The carrier gas may be an inert gas, such as an argon-containing gas, a helium-containing gas, a xenon-containing gas, other suitable inert gas, or a combination thereof. In some embodiments, a bottom-up deposition process is implemented to fill backside source/drain via openings 200 with source/drain via material 230′ (e.g., tungsten or cobalt) from bottom to top. The bottom-up deposition process (e.g., selective CVD) may include flowing a metal-containing precursor (e.g., a tungsten-containing precursor, such as WF₆ and/or WCl₅, or a cobalt-containing precursor), a reactant precursor (e.g., H₂, other suitable reactant gas, or a combination thereof), and a carrier gas into a process chamber and tuning deposition parameters to selectively grow source/drain via material 230′ from backside silicide layers 220 and/or metal seed layers while limiting growth of source/drain via material 230′ from dielectric materials (e.g., via spacers 210). The deposition parameters may include deposition precursors (e.g., metal precursors and/or reactant precursors), precursor flow rates, deposition temperature, deposition time, deposition pressure, source power, bias voltage, bias power, other suitable deposition parameters, or a combination thereof. In some embodiments, the bottom-up deposition process includes multiple deposition/etch cycles.

Referring to FIG. 1 and FIG. 14, method 10 at block 65 includes performing a planarization process (e.g., CMP) to remove excess source/drain via material 230′, such as that disposed over bilayer hard mask 180. Remainders of source/drain via material 230′, which fill backside source/drain via openings 200 and openings 190, form backside source/drain vias 230. The planarization process further removes an upper layer of the bilayer hard mask, such as hard mask layer 184 of bilayer hard mask 180, such that backside source/drain vias 230 and hard mask layer 182 form backside BS of device 100. In such embodiments, the planarization process may be performed until reaching and/or exposing hard mask layer 182, and hard mask layer 182 may function as a planarization stop layer (e.g., a CMP stop layer). Bottom surfaces of backside source/drain vias 230 may be planarized, such that a bottom surface of hard mask layer 182 and the bottom surfaces of backside source/drain vias 230 form a substantially planar surface.

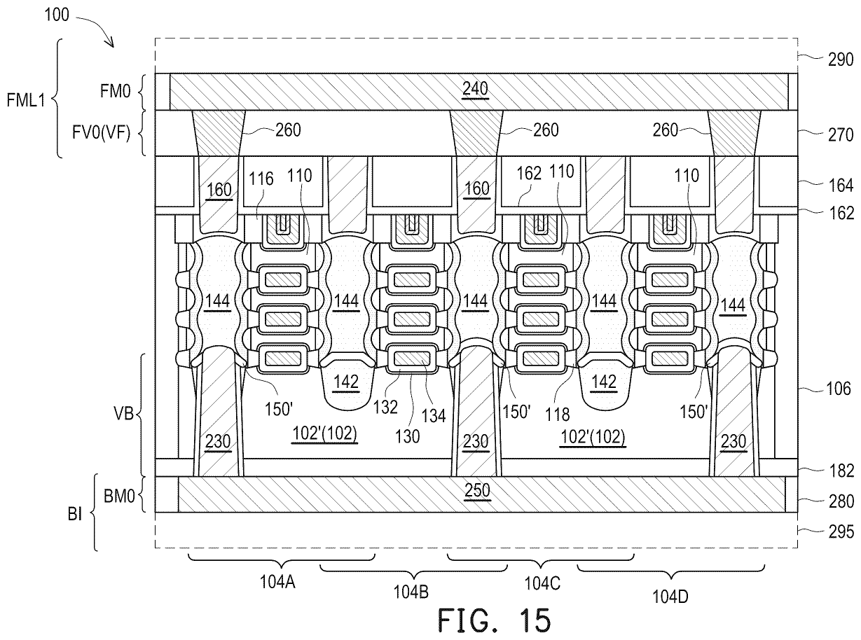

Processing associated with forming frontside source/drain contacts 160 and backside source/drain vias 230 may generally be referred to as middle-of-line (MOL) processing, which generally refers to fabricating MOL interconnects that physically and/or electrically connect FEOL features (e.g., electrically active features of a device) to first metallization layers (levels) formed during back-end-of-line (BEOL) processing. Processing may further include BEOL processing to form frontside routing layers and/or backside routing layers (generally referred to as BEOL features) that are electrically connected to frontside source/drain contacts 160 and backside source/drain vias 230. For example, referring to FIG. 1 and FIG. 15, method 10 at block 80 includes forming a frontside power rail (e.g., a frontside power rail 240) connected to the frontside source/drain contact (e.g., one or more of frontside source/drain contacts 160) and a backside power rail (e.g., a backside power rail 250) connected to the backside source/drain via (e.g., one or more of backside source/drain vias 230). The backside power rail is formed on a lower layer of the bilayer hard mask, such as hard mask layer 182 of bilayer hard mask 180. Frontside power rail 240 is electrically connected to frontside source/drain contacts 160 by frontside source/drain vias 260, and backside power rail 250 is electrically and physically connected to backside source/drain vias 230. Accordingly, some of source/drains 120 are electrically connected to both frontside power rail 240 (e.g., by frontside source/drain contacts 160 and frontside source/drain vias 260) and backside power rail 250 (e.g., by backside source/drain vias 230), such that power may be delivered to transistors 104A-104D by frontside power rail 240 (via frontside source/drain vias 260 and frontside source/drain contacts 160) and/or backside power rail 250 (via backside source/drain vias 230). Providing transistors 104A-104D with dual-side power rails lowers resistance associated with power delivery, which may reduce IR drop and improve performance of device 100. Further, because hard mask layer 182 (e.g., a dielectric layer, such as a silicon nitride layer) remains between backside power rail 250 and substrate 102, electrical isolation is improved between backside power rail 250 and gate stacks 114 and between backside power rail 250 and source/drains 120, which may improve performance of device 100. Further, providing dual-side power rails reduces an area consumed by device 100. In some embodiments, frontside power rail 240 is electrically connected to backside power rail 250. In some embodiments, source/drains 120 that are electrically connected to both frontside power rail 240 and backside power rail 250 are sources of transistors 104A-104D. In such embodiments, other source/drains 120 of transistors 104A-104D may be drains thereof, which may be electrically connected to ground. Different embodiments may have different advantages, and no particular advantage is required of any embodiment.

In some embodiments, before forming frontside power rail 240, processing may include flipping over device 100, such that device 100 is oriented upright (e.g., frontside FS thereof is facing up and backside BS thereof is facing down), and performing a thinning process and/or a de-bonding process to remove carrier substrate 170 and bonding layer 178 from frontside FS of device structure 100. For example, a planarization process (e.g., CMP) and/or an etching process removes carrier substrate 170 and bonding layer 178, thereby exposing frontside source/drain contacts 160 and the second-level dielectric layer (e.g., ILD layer 164). The planarization process may stop upon reaching frontside source/drain contacts 160 and/or the second-level dielectric layer. In some embodiments, carrier substrate 170 and bonding layer 168 are removed after forming backside source/drain vias 230. In some embodiments, carrier substrate 170 and bonding layer 168 are removed after forming backside power rail 250.

Frontside power rail 240 and frontside source/drain vias 260 may form a portion of a first frontside metallization layer/level of a frontside multilayer interconnect (FMLI). Forming the first frontside metallization layer/level may include forming a dielectric layer 270 over the second-level dielectric layer (e.g., ILD1, such as ILD layer 164 and/or CESL 162), patterning dielectric layer 270 to forming openings therein that expose frontside source/drain contacts 160, and forming electrically conductive material(s) in the openings to form vias 260, frontside power rail 240 (e.g., a metal line), other metal lines, or a combination thereof. Metal lines of the first frontside metallization layer (e.g., frontside power rail 240 and/or other metal lines) may collectively be referred to as a frontside metal zero (FM0) layer (and individually referred to as FM0 metal lines). Vias of the first frontside metallization layer (e.g., frontside source/drain vias 260) may collectively be referred to as a frontside via zero (FV0) layer (and individually referred to as FV0 (or VF) vias). In such embodiments, the first frontside metallization layer is a bottom routing layer of the frontside MLI, the FM0 layer is a bottom frontside metal line layer of the frontside MLI, and the FV0 layer is a bottom via layer of the frontside MLI. In some embodiments, dielectric layer 270 is a third-level dielectric layer (e.g., an ILD2, which may include an ILD layer over a CESL). In some embodiments, dielectric layer 270 includes a third-level dielectric layer (e.g., an ILD2) and a fourth-level dielectric layer (e.g., an ILD3, which may include an ILD layer over a CESL), where vias 260 are formed in the third-level dielectric layer and frontside power rail 240 is formed in the fourth-level dielectric layer.

Backside power rail 250 may form a portion of a first backside metallization layer/level of a backside interconnect (BI) structure, which may be a backside power delivery network (PDN) (e.g., routing structure for delivering power to device 100 from a backside). Forming the first backside metallization layer/level may include forming a dielectric layer 280 over hard mask 182, patterning dielectric layer 280 to forming openings therein that expose backside source/drain vias 230, and forming electrically conductive material(s) in the openings to form backside power rail 250 (e.g., a metal line) and/or other metal lines. Metal lines of the first backside metallization layer (e.g., backside power rail 250 and/or other metal lines) may collectively be referred to as a backside metal zero (BM0) layer (and individually referred to as BM0 metal lines). In such embodiments, the first backside metallization layer is a bottom backside routing layer, which may be a portion of a backside MLI and/or other backside interconnect structure, and the BM0 layer is a bottom backside metal line layer. In some embodiments, dielectric layer 280 includes an ILD layer and may include a CESL.

Frontside BEOL processing may include forming additional metallization layers (levels) 290 of frontside MLI over the first frontside metallization layer, and backside BEOL processing may include forming additional metallization layers (levels) 295 of BI structure over the first backside metallization layer. For example, frontside BEOL processing includes forming a second frontside metallization layer (i.e., a frontside metal one layer (FM1 level) and a frontside via one layer (FV1 level)), a third frontside metallization layer (i.e., a frontside metal two layer (FM2 level) and a frontside via two layer (FV2 level)), a fourth frontside metallization layer (i.e., a frontside metal three layer (FM3 level) and a frontside via three layer (FV3 level)), and so on to a topmost frontside metallization layer (i.e., a frontside metal X layer (FMX level) and a frontside via X layer (FVX level)). X is an integer greater than or equal to 1. Each level of frontside MLI includes a respective patterned electrically conductive layer (e.g., conductive lines, conductive vias, conductive contacts, or a combination thereof) disposed in a respective insulation layer (e.g., an ILD layer and/or a CESL). For example, FV0 level includes a portion of dielectric layer 270 having FV0 vias disposed therein, and FM0 level includes a portion of dielectric layer 270 having FM0 lines disposed therein. Backside BEOL processing may also include forming various backside metallization layers, such as a second backside metallization layer having a backside metal one layer (BM1 level) and a backside via one layer (BV1 level) connected to the first backside metallization layer. For example, one or more BM1 lines may be electrically connected to backside power rail 250 by BV1 vias. Though frontside MLI and BI structure is depicted with a given number of metallization layers within a given number of dielectric layers, frontside MLI and BI structure may have more or less conductive line layers, via layers, and dielectric layers depending on design requirements. In some embodiments, frontside MLI has seven to fourteen frontside metallization layers (e.g., FM0 to FM14 and FV1 to FV14), and BI has less backside metallization layers than frontside MLI.

FM0-FMX lines, BM0 lines, and other backside lines may be referred to as BEOL lines, and FV0-FVX vias and backside vias may be referred to as BEOL vias. BEOL lines and BEOL vias are formed by any suitable process and include any suitable materials, layers, configurations, etc. In some embodiments, BEOL interconnect structures, such as a metal line and a metal via of a given metallization level (e.g., an FM0 interconnect structure may include a respective FV0 via and a respective FM0 line connected thereto) may be formed by a dual damascene process, which involves depositing materials for the metal via and the metal line at the same time. In such embodiments, the metal via and the metal line may share a liner and a metal plug, instead of each having a respective and distinct liner and metal plug. In some embodiments, the dual damascene process includes performing a patterning process to form an interconnect opening that extends through a dielectric layer (e.g., dielectric layer 270) to expose an underlying interconnect structure (e.g., a metal line thereof). The patterning process may include a first lithography step and a first etch step to form a trench opening of the interconnect opening (which corresponds with the metal line) in the dielectric layer, a second lithography step and a second etch step to form a via opening of the interconnect opening (which corresponds with the metal via) in the dielectric layer, and in some embodiments, a third etch step to remove a portion of the dielectric layer to expose the underlying interconnect structure. The first lithography/first etch step and the second lithography/second etch step may be performed in any order (e.g., trench first via last or via first trench last). In some embodiments, the first etch step and the second etch step are each configured to selectively remove an ILD layer with respect to a patterned mask layer and CESL, while the third etch step is configured to selectively remove the CESL with respect to the ILD and underlying BEOL interconnect structure. After performing the patterning process, the dual damascene process may include performing a first deposition process to form a barrier/liner material that partially fills the interconnect opening, performing a second deposition process to form a metal bulk material over the barrier/liner material, where the metal bulk material fills a remainder of the interconnect opening, and performing a planarization process to remove excess metal bulk material and barrier/liner material. The barrier/liner material and the metal bulk material fill the trench opening and the via opening of the interconnect opening without interruption, such that the liner and metal plug each extend continuously from metal line to via without interruption.

Frontside MLI electrically connects devices of device 100 (e.g., transistors 104A-104D), components of device 100, devices (e.g., a memory device) within frontside MLI, components of frontside MLI, or a combination thereof to one another and/or to external devices/components, such that the various devices and/or components can operate as needed. Frontside MLI includes a combination of insulation layers and electrically conductive layers (e.g., patterned metal layers formed by conductive lines, conductive vias, conductive contacts, or a combination thereof) arranged to form interconnect/routing structures. The conductive layers form vertical interconnect structures, such as device-level contacts, via contacts, and vias, that connect horizontal interconnect structures, such as conductive lines, in different layers/levels (or different planes) of frontside MLI. In some embodiments, the interconnect structures route electrical signals between devices and/or components of device 100 and/or frontside MLI. In some embodiments, the interconnect structures route electrical signals to and/or from the devices and/or the device components of frontside MLI and/or frontside MLI. During operation of device 100, frontside source/drain contacts 160, backside source/drain vias 230, the first frontside metallization layer (e.g., FM0 level having frontside power rail 240 and frontside source/drain vias 260), the first backside metallization layer (e.g., BM0 having backside power rail 250), other metallization layers of frontside MLI, other metallization layers of the backside interconnect structure, or a combination thereof may route signals between the devices and/or the components thereof and/or distribute signals (e.g., clock signals, voltage signals, ground signals, other signals, or a combination thereof) to/from the devices, the components of the devices, external devices, or a combination thereof. For example, power may be delivered to transistors 104A-104D by frontside power rail 240 (via frontside source/drain vias 260 and frontside source/drain contacts 160) and/or backside power rail 250 (via backside source/drain vias 230). In some embodiments, MOL features/structures form a portion of frontside MLI.

The present disclosure provides for many different embodiments. An exemplary method includes forming a bilayer hard mask over a backside of a substrate. The bilayer hard mask includes a first hard mask layer over the backside of the substrate and a second hard mask layer over the first hard mask layer. The method further includes patterning the bilayer hard mask to form a hard mask opening therein that exposes a portion of the substrate that overlaps a source/drain, forming a backside source/drain via opening in the substrate that exposes the source/drain by patterning the exposed portion of the substrate using the bilayer hard mask, forming a backside source/drain via in the backside via opening and the hard mask opening, and, after removing the second hard mask layer, forming a backside metallization layer over the first hard mask layer and the backside source/drain via.

In some embodiments, the method further includes extending the backside source/drain via opening by removing a first semiconductor portion of the source/drain to expose a source/drain isolation structure of the source/drain and extending the backside source/drain via opening through the source/drain isolation structure of the source/drain when forming via spacers along sidewalls of the backside source/drain via opening. In some embodiments, forming the via spacers includes deposing a dielectric layer over the second hard mask layer, along sidewalls of the hard mask opening formed by the bilayer hard mask, along sidewalls of the backside source/drain via opening formed by the substrate, and over a bottom of the backside source/drain via opening formed by the exposed source/drain, and etching the dielectric layer. The etching may remove the dielectric layer from over the second hard mask layer and the bottom of the backside source/drain via opening. In some embodiments, the first hard mask layer, the source/drain isolation structure, and the via spacers include silicon and nitrogen.

In some embodiments, the method further includes forming a backside silicide layer over the exposed source/drain before forming the backside source/drain via. In some embodiments, removing the second hard mask layer includes performing a planarization process that stops upon reaching the first hard mask layer. In some embodiments, forming the backside source/drain via opening includes depositing an electrically conductive material over the second hard mask layer that fills the backside source/drain via opening and performing the planarization process to remove excess electrically conductive material.

In some embodiments, the method further includes applying a thinning process to the backside of the substrate before forming the bilayer hard mask. In some embodiments, the method further includes forming a frontside source/drain contact to the source/drain and forming a frontside metallization layer over the frontside source/drain contact.

Another exemplary method includes forming a frontside source/drain contact on a source/drain of a transistor, forming a backside source/drain via on the source/drain of the transistor, forming a frontside power rail over the frontside source/drain contact, and forming a backside power rail over the backside source/drain via. The frontside power rail is electrically connected to the frontside source/drain contact and the backside power rail is physically and electrically connected to the backside source/drain via. Forming the backside source/drain via may include forming a first hard mask layer over a backside of a substrate, forming a second hard mask layer over the first hard mask layer, patterning the first hard mask layer and the second hard mask layer, patterning the substrate using the patterned first hard mask layer and the patterned second hard mask layer, and removing the patterned second hard mask layer. The patterned first hard mask layer may remain between the backside power rail and the backside of the substrate. In some embodiments, the method further includes applying a thinning process to the backside of the substrate before forming the backside source/drain via. In some embodiments, the source/drain is a source of a transistor.

In some embodiments, forming the first hard mask layer includes depositing a nitride layer over the backside of the substrate and forming the second hard mask layer includes depositing an oxide layer over the nitride layer. In some embodiments, a first thickness of the first hard mask layer is less than a second thickness of the second hard mask layer.

In some embodiments, forming the backside source/drain via includes depositing an electrically conductive material in the patterned substrate, the patterned first hard mask layer, and the patterned second hard mask layer and performing a planarization process that removes the patterned second hard mask layer. The planarization process may stop upon reaching the patterned first hard mask layer. In some embodiments, forming the backside source/drain via includes forming a backside silicide layer and forming the frontside source/drain contact includes forming a frontside silicide layer. In such embodiments, the source/drain is between the backside source/drain via and the frontside source/drain contact.

In some embodiments, forming the backside source/drain via includes recessing the source/drain and forming the backside source/drain via includes etching the source/drain isolation structure of the source/drain to expose a semiconductor portion of the source/drain. The recessing may stop upon reaching a source/drain isolation structure of the source/drain.

An exemplary device includes a frontside power rail disposed over a frontside of a substrate, a backside power rail disposed over a backside of the substrate, and an epitaxial source/drain structure disposed between the frontside power rail and the backside power rail. The epitaxial source/drain structure is connected to the frontside power rail by a frontside source/drain contact, the epitaxial source/drain structure is connected to the backside power rail by a backside source/drain via, and the backside source/drain via is disposed in the substrate. The device further includes a dielectric layer disposed between the substrate and the backside power rail, wherein the backside source/drain via extends through the dielectric layer.

In some embodiments, the device further includes a backside silicide layer disposed between the backside source/drain via and a backside of the epitaxial source/drain structure and a frontside silicide layer disposed between the frontside source/drain contact and a frontside of the epitaxial source/drain structure. In such embodiments, the epitaxial source/drain structure is disposed between the backside silicide layer and the frontside silicide layer.

In some embodiments, the backside source/drain via extends through a source/drain isolation structure of the epitaxial source/drain structure and the source/drain isolation structure is disposed between the via spacers and the epitaxial source/drain structure. The via spacers are disposed along sidewalls of the backside source/drain via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
after forming a source/drain contact over a first side of a source/drain structure at a first side of a substrate, depositing a first silicon nitride layer over a second side of the substrate, wherein the first side of the substrate is opposite the second side of the substrate and the source/drain structure includes a semiconductor portion and an isolation portion;
depositing a silicon oxide layer over the first silicon nitride layer, wherein the silicon oxide layer has a first thickness, the first silicon nitride layer has a second thickness, and the second thickness is different from the first thickness;
forming a source/drain via opening in the silicon oxide layer, the first silicon nitride layer, and the substrate, wherein the source/drain via opening overlaps a second side of the source/drain structure that is opposite the first side of the source/drain structure;
depositing a second silicon nitride layer over the silicon oxide layer, wherein the second silicon nitride layer partially fills the source/drain via opening;
extending the source/drain via opening through the second silicon nitride layer and the isolation portion of the source/drain structure, wherein the extended source/drain via opening exposes the semiconductor portion of the source/drain structure;
forming a source/drain via in the extended source/drain via opening and over the second side of the source/drain structure, wherein the silicon oxide layer is removed from over the second side of the substrate while forming the source/drain via; and
forming a first power rail over the source/drain contact and a second power rail over the source/drain via, wherein the second power rail is formed on the first silicon nitride layer.

2. The method of claim 1, wherein the forming the source/drain via opening in the silicon oxide layer, the first silicon nitride layer, and the substrate includes:
performing a first etch that selectively removes the silicon oxide layer and the silicon nitride layer with respect to the substrate; and
performing a second etch that selectively removes the substrate with respect to the silicon oxide layer and the silicon nitride layer.

3. The method of claim 2, wherein the second etch further selectively removes the substrate with respect to the isolation portion of the source/drain structure.

4. The method of claim 2, wherein:
the semiconductor portion of the source/drain structure includes a first side semiconductor portion and a second side semiconductor portion;
the isolation portion of the source/drain structure is disposed between the first side semiconductor portion and the second side semiconductor portion; and
the second etch further selectively removes the second side semiconductor portion with respect to the isolation portion of the source/drain structure.

5. The method of claim 1, wherein the extending the source/drain via opening through the second silicon nitride layer and the isolation portion of the source/drain structure includes thinning the second silicon nitride layer.

6. The method of claim 1, wherein:
the isolation portion of the source/drain structure is a third silicon nitride layer; and
the extending of the source/drain via opening through the second silicon nitride layer and the isolation portion of the source/drain structure includes performing an etch that selectively removes the second silicon nitride layer and the third silicon nitride layer with respect to the semiconductor portion of the source/drain structure and the silicon oxide layer.

7. The method of claim 1, wherein the forming of the source/drain via in the extended source/drain via opening and over the second side of the source/drain structure includes a planarization process that removes the silicon oxide layer, wherein the first silicon nitride layer provides a planarization stop for the planarization process.

8. The method of claim 1, further comprising performing a silicidation process after extending the source/drain via opening and before forming the source/drain via.

9. The method of claim 1, wherein the extending of the source/drain via opening through the second silicon nitride layer and the isolation portion of the source/drain structure leaves remnants of the isolation portion of the source/drain structure between the second silicon nitride layer and the semiconductor portion of the source/drain structure.

10. A device structure comprising:
a gate disposed between a first source/drain and a second source/drain;
a first interconnect structure disposed over a first side of the first source/drain, wherein the first interconnect structure includes a source/drain contact disposed on the first side of the first source/drain, a first source/drain via disposed on the source/drain contact, and a first power rail disposed on the first source/drain via; and
a second interconnect structure disposed over a second side of the first source/drain, wherein the second side of the first source/drain is opposite the first side of the first source/drain and the second interconnect structure includes a second source/drain via disposed on the second side of the first source/drain and a second power rail disposed on the second source/drain via.

11. The device structure of claim 10, wherein the gate is disposed between the first source/drain and the second source/drain along a direction, the first power rail extends lengthwise along the direction, and the second power rail extends lengthwise along the direction.

12. The device structure of claim 10, wherein:
the first source/drain via is disposed in an interlayer dielectric layer; and
the second source/drain via is disposed in a semiconductor substrate.

13. The device structure of claim 12, wherein a dielectric layer is disposed between sidewalls of the second source/drain via and the semiconductor substrate.

14. The device structure of claim 13, wherein a remnant of a source/drain isolation structure is disposed between the dielectric layer and the first source/drain.

15. The device structure of claim 10, further comprising a first silicide layer and a second silicide layer, wherein the first silicide layer is disposed between the first side of the first source/drain and the source/drain contact and the second silicide layer is disposed between the second side of the first source/drain and the second source/drain via.

16. The device structure of claim 10, wherein the source/drain contact is a first source/drain contact, the device structure further comprising a third interconnect structure disposed over the second source/drain, wherein the third interconnect structure includes a second source/drain contact disposed on a first side of the second source/drain.

17. The device structure of claim 10, wherein:
the gate, the first source/drain, and the second source/drain belong to a transistor;
the first source/drain is a source of the transistor; and
the second source/drain is a drain of the transistor.

18. A device structure comprising:
a gate disposed between a source and a drain, wherein the source is sandwiched between and connected to a frontside power rail and a backside power rail;
a frontside silicide and a backside silicide disposed on the source, wherein a frontside interface between the frontside silicide and the source is curved up towards the frontside power rail and a backside interface between the backside silicide and the source is curved down towards the backside power rail; and
a backside source via that extends from the source to the backside power rail, wherein the backside silicide is disposed between the source and the backside source via.

19. The device structure of claim 18, wherein the frontside power rail belongs to a first level metallization layer of a frontside interconnect structure, and the backside power rail belongs to a first level metallization layer of a backside interconnect structure.

20. The device structure of claim 18, further comprising:
a stack of semiconductor layers disposed between the source and the drain, wherein the gate is disposed over and wraps the stack of semiconductor layers;
an inner spacer disposed between the source and a portion of the gate disposed below a bottom of the stack of semiconductor layers; and
a remnant of a source/drain isolation structure disposed between the inner spacer and a sidewall of the backside source via.
